(19) United States
(12) Patent Application Publication
(10) Pub. No.: US 2016/0219728 A1
(43) Pub. Date: Jul. 28, 2016

(54) METHOD AND APPARATUS FOR PROVIDING INTERCHANGEABLE MODULES SUCH AS A POWER OUTLET MODULE

(71) Applicant: Gaurav Balyan, Princeton, NJ (US)

(72) Inventor: Gaurav Balyan, Princeton, NJ (US)

(21) Appl. No.: 14/603,603

(22) Filed: Jan. 23, 2015

(51) Int. Cl. H05K 5/02; H05K 5/00

(52) U.S. Cl. CPC H05K 5/0208; H05K 5/0017

(57) ABSTRACT

The present principles generally relate to an apparatus and a method for providing an interchangeable module, such as e.g., an AC power outlet. In one exemplary embodiment, the present principles provide a modular power distribution system which is safe and easy to use. The present principles allow a layman with no experience to quickly, conveniently and safely change or replace, e.g., a power outlet or switch without any tool. The system and method according to the present principles also would not require power to be first disconnected at the fuse box since the present exemplary modules to be described are conveniently hot pluggable in a safe manner.

### BACKGROUND OF THE INVENTION

1. Field of the Invention

The present principles generally relate to an apparatus and a method for providing an interchangeable module, such as e.g., an AC power outlet. In one exemplary embodiment, the present principles provide a modular power distribution system which is safe and easy to use. The present principles allow a layman with no experience to quickly, conveniently and safely change or replace, e.g., a power outlet or switch without any tool. The system and method according to the present principles also would not require power to be first disconnected at the fuse box since the present exemplary modules to be described are conveniently hot pluggable in a safe manner.

2. Background Information

Various modular power distribution system and power outlets have been proposed.

For example, U.S. Pat. No. 7,192,289 issued to Kowalski, according to its Abstract, proposed a module system for power distribution includes sealed modules for providing control or access to the power, wherein the module system allows interconnection to a modular circuit breaker panel for monitoring power consumption.

U.S. Pat. No. 6,540,536, issued to Young, according to its Abstract, proposed a modular electrical system kit which interconnects a plurality of electrical wires of a power entry to one electrical outlet. The modular electrical system kit includes a plurality of circuit selectors, with each circuit selector being configured for interconnecting a respective selected combination of power entry wires to the one electrical outlet.

U.S. Pat. No. 5,915,984 issued to Rupert et al., according to its Abstract, proposed a modular electrical outlet including a housing; a pair of plug-in connectors carried by and disposed at opposing ends of the housing; and a conductor disposed within the housing. Each of the connectors includes a plurality of terminal receiving openings. The conductor includes a pair of blade receiving sockets, with a longitudinal axis extending between the blade receiving sockets. The conductor includes a pair of terminals at opposing ends thereof, with each terminal being offset from the longitudinal axis. The conductor may be selectively positioned in the housing at one of two reversible positions. The conductor may be selectively disposed within the housing in a first position such that each terminal is received within an associated terminal receiving opening of a respective connector, and a second position such that each terminal is received within an associated terminal receiving opening of the other respective connector.

In addition, US 2012/0239733, titled “Modular Intelligent Power System”, according to its Abstract, proposed a system for monitoring or controlling conditions or apparatuses in a home, business or other suitable place. The system includes a first master module that is operative to communicate with a device over an Internet network. The system further includes a server that is operatively connected to the device and the first master module. The server is operative to allow communication between the first master module and the device.

### SUMMARY OF THE INVENTION

The present inventor recognizes that, however, the existing systems and methods for providing a modular power distribution system do not provide a fast, safe, universal and ecstatically-pleasing way for a layman to quickly change the different outlets or functional modules of the system.

That is, for example, the existing systems and methods do not provide an outlet module with an integrated key locking mechanism so that an unauthorized person or a child cannot remove the module. The existing systems and methods also do not provide an integrated face plate which when the outlet module is mounted to the wall, the face plate is automatically flushed mounted against the wall in one simple push and locked step to provide an ecstatically-pleasing finish.

The present principles, therefore, provide an easy and simple way for changing electrical outlets without the need for complicated and potentially hazardous rewiring typically required. In addition, various types of interchangeable modules, such as e.g., an AC power outlet, a converted USB DC power outlet, a power switch, an Ethernet connector outlet, a built-in wireless extender or router, thermostat, and any of the above combinations may all share the same interchangeable, plug-in configuration.

Therefore, in accordance with an exemplary embodiment, a system is presented, comprising:

a plurality of interchangeable modules;

a central controller configured to monitor and control the plurality of interchangeable modules;

wherein at least one of the plurality of interchangeable modules comprises:
a power supply socket for supplying power to an external device;
an integrated locking mechanism;
a protrusion coupled to the integrated locking mechanism;
a module connector;
an integrated face plate positioned in front side of the at least one of the plurality of interchangeable modules; and
wherein the protrusion is extended by the integrated locking mechanism in one position of the integrated locking mechanism to secure the at least one of the plurality of interchangeable modules to a work box, and the integrated face plate is flush mounted against a wall when the at least one of the plurality of interchangeable modules is mounted to the work box via the module connector.

In another exemplary embodiment, an interchangeable module is presented comprising:

a power supply socket for supplying power to an external device;

an integrated locking mechanism;

a protrusion coupled to the integrated locking mechanism;

a module connector;

an integrated face plate positioned in front side of the interchangeable module; and

wherein the protrusion is extended by the integrated locking mechanism in one position of the integrated locking mechanism to secure the interchangeable module to a work box, and the integrated face plate is flush mounted against a wall when the interchangeable module is mounted to the work box via the module connector.

In another exemplary embodiment, an interchangeable module is presented comprising:

at least one of a plurality of functional components;

an integrated locking mechanism;

a protrusion coupled to the integrated locking mechanism;

a module connector;

an integrated face plate positioned in front side of the module; and

wherein the protrusion is extended by the integrated locking mechanism in one position of the integrated locking mechanism to secure the module to a work box and the integrated face plate is flush mounted against a wall when the module is mounted to the work box via the module connector.

In another exemplary embodiment, a face plate for a work box is presented, comprising:

a front face;

a plurality of protrusions on one or more sides of the face plate and extending outwardly in the rear ward direction away from the front face; and

wherein the face plate is configured to be mounted to the work box by the plurality of protrusions.

### DETAILED DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

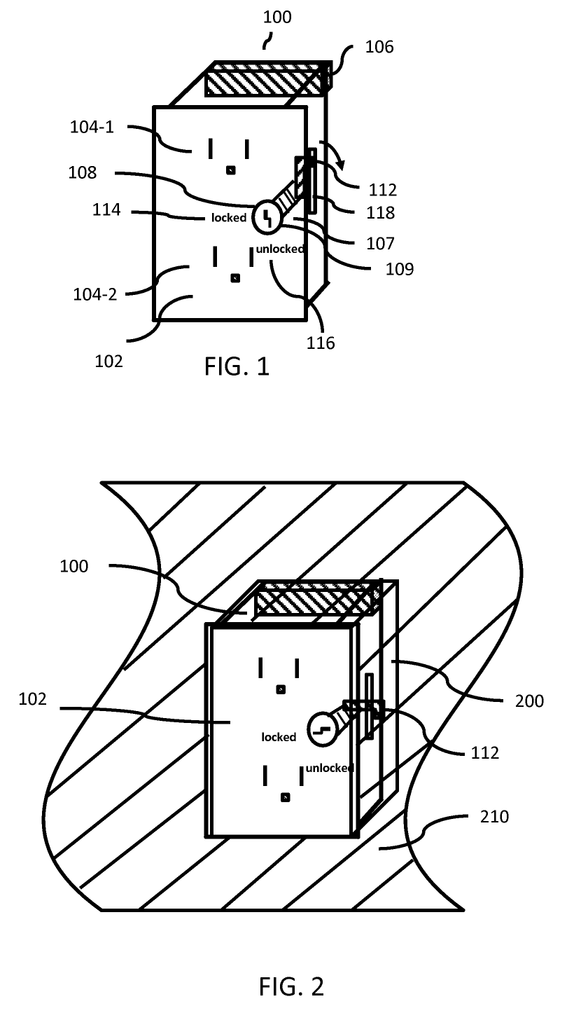

FIG. 1 shows an exemplary modular apparatus according to the present principles;

FIG. 2 shows an example modular apparatus being securely mounted to an exemplary work box according to the present principles;

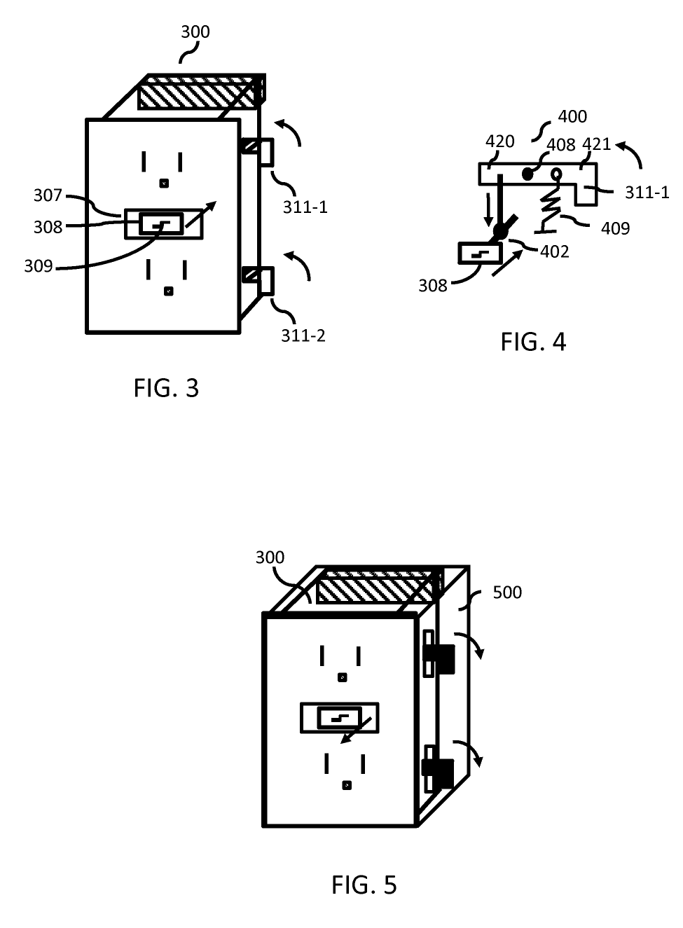

FIG. 3 shows another exemplary module according to the present principles;

FIG. 4 shows an exemplary locking mechanism and exemplary protrusions according to the present principles;

FIG. 5 shows another exemplary module being securely mounted to an exemplary work box according to the present principles;

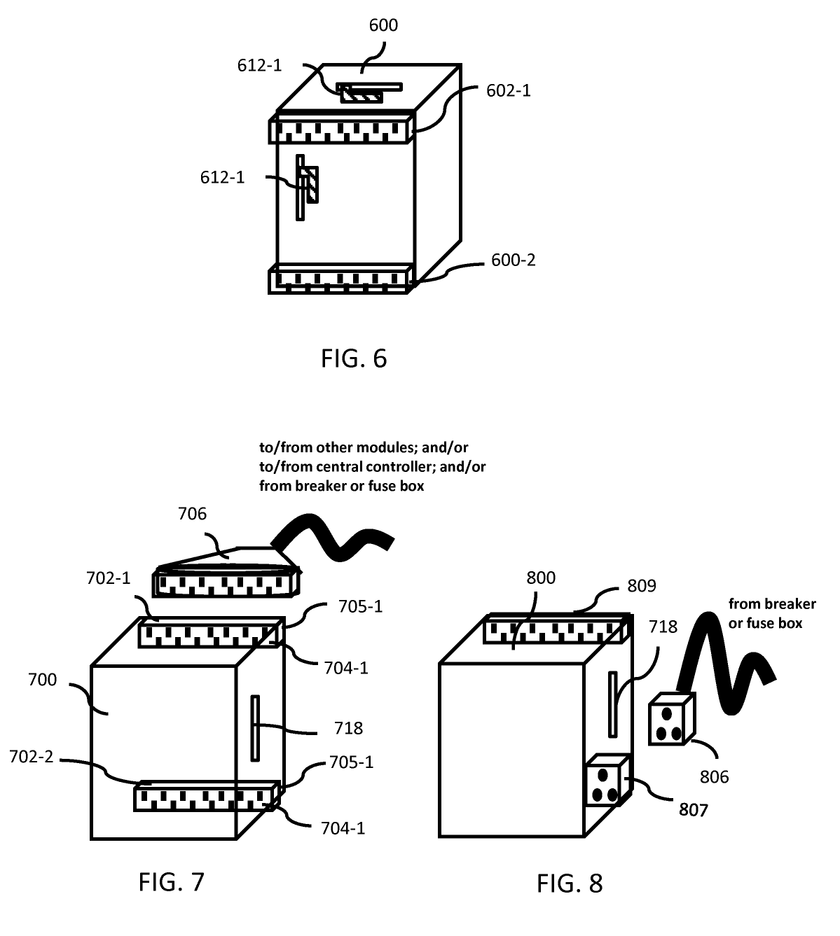

FIG. 6 shows a rear view of an example module according to the present principles;

FIG. 7 shows an exemplary work box, connector and connector cable according to the present principles; and

FIG. 8 shows another exemplary work box with a separate AC connector according to the present principles;

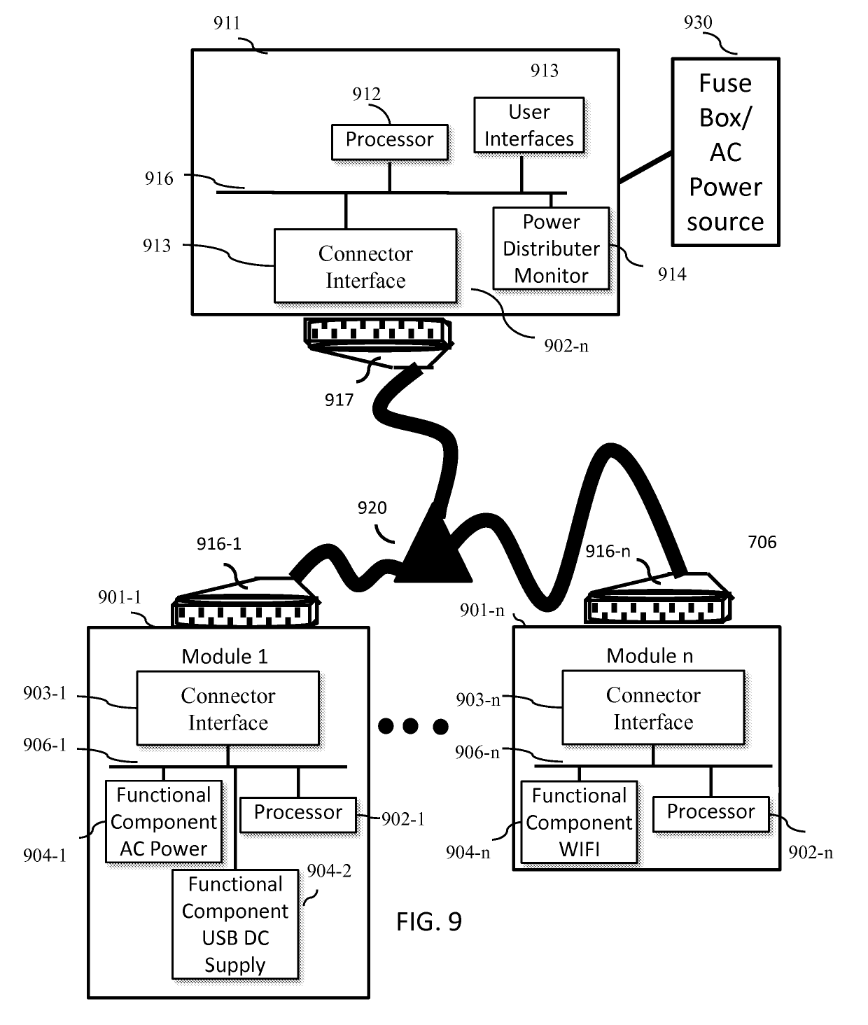

FIG. 9 shows an exemplary modular system incorporating a plurality of different interchangeable modules according to the present principles;

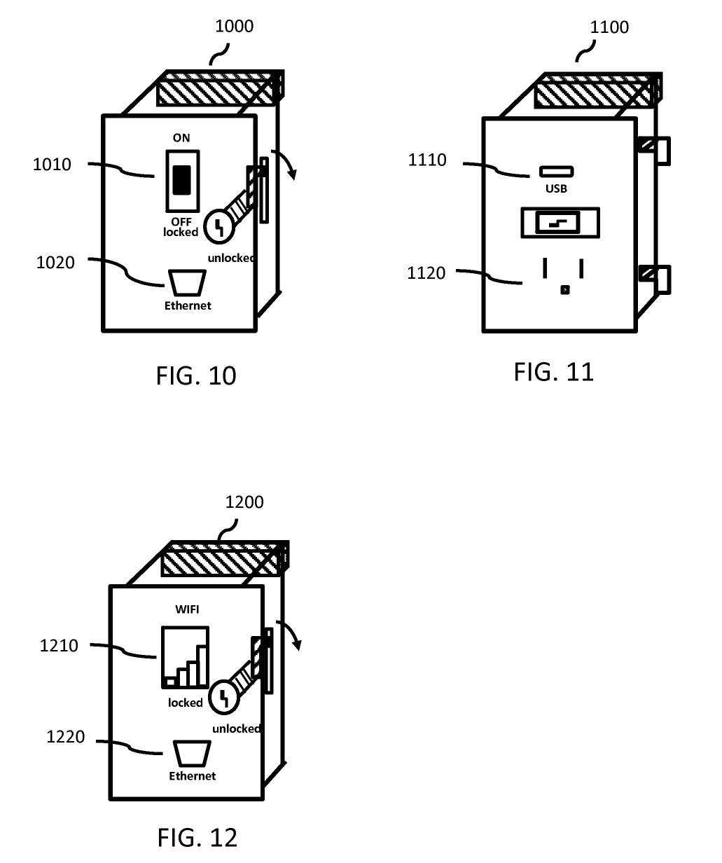

FIG. 10 to FIG. 12 show additional exemplary embodiments of different modules according to the present principles;

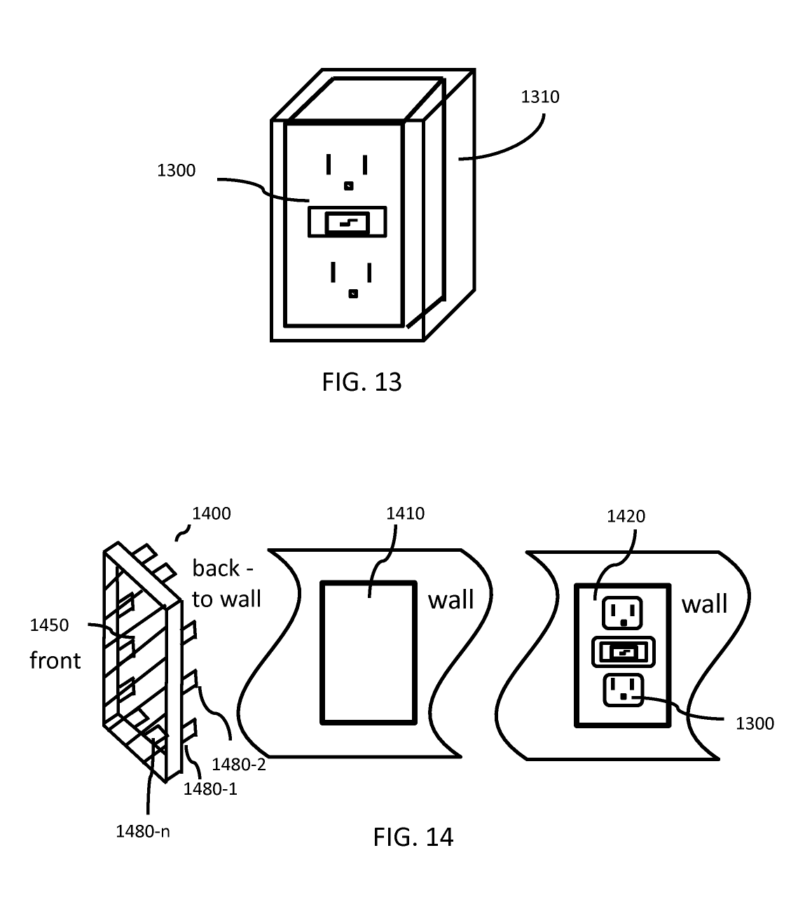

FIG. 13 shows an exemplary module which does not have an integrated face place according to the present principles; and

FIG. 14 shows an exemplary wall cover face plate according to the present principles.

The examples set out herein illustrate exemplary embodiments of the present principles. Such examples are not to be construed as limiting the scope of the invention in any manner.

### DETAILED DESCRIPTION

The present principles provide a modular power distribution system which is safe and easy to use. The present principles allow a layman with no experience to quickly, conveniently and safely change or replace, e.g., a power outlet module or switch module without any tool. The system and method according to the present principles also would not require power to be first disconnected at the fuse box, since the present modules to be described are conveniently hot pluggable in a safe manner.

In addition, the present principles provide an integrated face plate with the replaceable module which when the module is plugged into a work box in the wall, the face plate is automatically flush mounted against the wall in one simple push and locked step to provide an ecstatically-pleasing finish. In addition, in one exemplary embodiment, a module is fitted with an integrated key locking mechanism so that an unauthorized person or a child cannot remove the module with a key.

In another exemplary aspect according to the present principles, a face plate may be provided separately and not integrated to an exemplary module. In addition, an exemplary quick-mount wall cover face plate is provided which may be used to quickly cover over a space in a wall which a work box may already reside, or the wall cover face plate may be quickly removed. This way, when the wall cover face plate according to the present principles is quickly removed, one of the exemplary modules according to the present principles may be quickly and easily mounted to an already existing work box if a need suddenly arises, without any tool. The quick cover face plate also provides an ecstatically-pleasing finish.

The present principles, therefore, provide an easy and simple way to change electrical outlets without the need for complicated and potentially hazardous rewiring typically required. In addition, various types of interchangeable modules, such as, e.g., an AC power outlet, a converted DC USB power outlet, a switch, an Ethernet connector outlet, a build-in wireless extender or router, a thermostat, any of the above combinations, and other functionalities may be provided, and/or be sharing the same plug-in configuration.

FIG. 1 shows an exemplary apparatus 100 according to the present principles. The exemplary interchangeable module 100 shown is a modular power AC outlet 100 according to the present principles. Module 100 may include one or more of exemplary power supply sockets 104-1 and 104-2 for supply power to an external device (not shown). One example of such a power supply is a 120V AC 3-wire power supply socket shown as 104-1 and 104-2 in FIG. 1, commonly found in the USA.

Module 100 may also comprise a module connector 106 in the back of the module. The detail of this module wire connector will be explained in more detail below. In addition, module 100 may also include an exemplary integrated locking mechanism 107 comprising, for example, a lock 108 having a key hole 109. The locking mechanism 107 is connected to a protrusion such as, e.g., a latch 112, so that when the lock 108 is turned by a key (not shown) in the clockwise direction from an “unlocked” position 116 to a “locked” position 114 as shown in FIG. 1, the latch 112 is extended out of an opening 118 of module 100.

FIG. 2 illustrates how this protrusion or latch 112 may be used to secure and lock module 100 into an exemplary electric outlet work box 200, when the module 100 is mounted and seated into the electrical outlet work box 200. As is well known in the art, in general, a work box is a box which is typically recessed into the wall for mounting of electrical outlets, switches or the like, and for making wire connections to the power lines from an electrical fuse box in the house. As shown in FIG. 2, once the latch 112 is in the protruded or extended position as shown, module 100 is securely mounted to the outlet workbox 200 and cannot be removed by an unauthorized person or a child without the key.

According to the present principles, the exemplary outlet module 100 may also include an integrated face plate 102 in the front side of the module 100 as shown in FIG. 1. The dimension of the integrated face plate 102 is larger than the rest of the module as shown in FIG. 1. Therefore, as shown in FIG. 2, when the module 100 is pushed into and mounted to an exemplary electric outlet work box 200, the integrated face plate 102 as well as module 100 may be mounted flushed against a wall 210. This would provide a neat and ecstatically-pleasing outer appearance for the mounting of the module 100 as shown in FIG. 2.

FIG. 3 shows another exemplary module 300 according to the present principles. Module 300 also illustrates another exemplary integrated locking mechanism 307 according to the present principles. The locking mechanism 307 comprises a portion 308 which is push-able toward the direction of the wall, only when a key (not shown) is inserted into the key hole 309. When the key-push-able portion 308 is pushed in the direction of the wall in one position, exemplary latches 311-1 and 311-2 shown in FIG. 2 will be retracted in the counterclockwise direction and not extended out as shown in FIG. 3. This would allow the module 300 to be inserted and mounted un-obstructively into an exemplary work box 500 as shown in FIG. 5. One skilled in the art can really appreciate that other types of locking, latching, and/or connecting mechanism may also be implemented without departing from the teaching of the present principles.

FIG. 4 illustrates in detail an exemplary integrated locking mechanism 307 of the exemplary module 300 as shown in FIG. 3. As illustrated, the key-push-able portion 308 is connected, through a lever or a gearing mechanism 402, to one end 420 of a latch such as, e.g., the upper latch 311-1 shown in FIG. 3. When the push-able portion 308 is pushed in the direction of the wall using a key (not shown), the lever or gearing mechanism 402 causes the latch 311-1 to move in the counterclockwise direction against a fulcrum point 408. In addition, the other end 421 of latch 311-1 is connected to a spring 409 which would return the latch 311-1 to the original locked position, when the push-able portion 308 is no longer being pushed in.

Although FIG. 4 illustrates an exemplary locking mechanism 400 only for the exemplary upper latch 311-1 shown in FIG. 3, one skilled in the art can readily appreciate that the same or similarly locking mechanism may be used for the lower latch 311-2 shown in FIG. 3. In addition, one skilled in the art can readily recognize that many other types of locking mechanisms may be used to implement the integrated locking mechanism shown in module 100 of FIG. 1 or module 300 of FIG. 3, without departing from the teachings of the present principles.

FIG. 5 shows when the module 300 in FIG. 3 has already been mounted, seated and connected to an exemplary work box 500. As shown in FIG. 5, the key-push-able portion 308 has already been retracted to the original position (i.e., with the key removed) such that the exemplary latches 311-1 and 311-2 have already returned to the protruding position by spring 409 shown in FIG. 4. In this position, module 300 is securely mounted and connected to work box 500. Therefore, module 300 cannot be removed without the key (which would allow push-able portion 308 to be pushed in), thereby preventing an unauthorized person or a child from removing the module 300.

FIG. 6 is a rear view of an exemplary interchangeable module 600 according to the present principles. As seen in FIG. 6, module 600 may comprise one or more module connectors 602-1 and 602-2 for connecting to mating connectors 702-1 and 702-2 of an exemplary work box 700 as shown in FIG. 7. One skilled in the art may readily appreciate that if the exemplary module connectors 602-1 and 602-2 shown in FIG. 6 are of the male type, then the mating connectors 702-1 and 702-2 on the work box 700 in FIG. 7 will be of the female type and vice versa, so that they may be mated and connected together.

In addition, although the exemplary module 600 in FIG. 6 shows one connector 602-1 on top and another connector 602-2 on the bottom of module 600, the number and positions of the connectors on an interchangeable module in a particular system are chosen as design choices, which may depend on a particular application of the system or mounting position of a typical module within a system. However, within a given system, home or premises, all the modules should preferably have the same connector configuration so that all the modules are easily pluggable and interchangeable.

Also, an exemplary protrusion or latch of a module according to the present principles may be positioned in one or more of sides of the module. For example, FIG. 6 shows that an exemplary latch 612-1 of the exemplary module 600 may be located on a vertical side of the module 600, or in addition, or in the alternative, on a horizontal side of the module 600.

As noted before, FIG. 7 shows an exemplary work box 700 according to the present principles. Also as noted before, work box 700 comprises one or more exemplary mating work box connectors 702-1 and 702-2 for mating on one side 704-1 or 704-2 with e.g., one or more module connectors 602-1 and 602-2 of the exemplary module 600 shown in FIG. 6. Furthermore, the other side 705-1 or 705-2 of connectors 702-1 and 702-2 may be connected to an integrated cable or wire connector 706 as shown in FIG. 7. The integrated cable or wire connector 706 is used to connect wires to and from other modules (not shown), a central controller, and/or a power distribution fuse box, and etc. The wires or cable in connection with connector 706 may be used to provide, e.g., Ethernet wires, control and status wires to and from different modules or a central controller, wires for power supplies to the modules, audio and video cables, AC power for a power outlet, and etc., to be described in more detail below.

FIG. 8 shows another exemplary electrical work box 800 according to the present principles. As shown in FIG. 8, the exemplary work box 800 has a separate AC power supply connector 802 for making a connection to an AC power supply source such as a fuse or a breaker box of a house, through a separate AC power connection cable 808. In this configuration, connector 809 as shown in FIG. 8 will be used for other purposes such as, e.g., providing wirings for Ethernet, for control and status signals to and from a central controller, or to and from other modules, for power supplies to the modules, audio and video cables, and etc. In addition, an opening 718 is shown on one side of module 700 so that an exemplary protrusion or latch such as 612-2 shown in FIG. 6 may protrude or extend out of the opening 718, so that the module 600 is secured and or locked as described above.

FIG. 9 shows an exemplary modular system incorporating a plurality of different interchangeable modules according to the present principles. As shown in FIG. 9, a plurality of interchangeable modules 901-1 to 901-n may be controlled and monitored, and associated power provided by a central monitoring and distribution controller 911. The central monitoring controller 911 may comprise a processor 912 for controlling and monitoring the different components of the central controller 911, through a processor bus 916. The different components of the controller 911 may comprise, for example, a connector interface 913 for connecting to a cable connector 917; user interfaces 913 such as, e.g., a keyboard and a display for controlling and displaying the status and functions of different modules 901-1 to 901-n shown in FIG. 9.

In addition, the central controller 911 may comprise a power distributor and monitor 914 which may be connected to a fuse/breaker box or the AC power source 930 for the entire premises in order to distribute and monitor power to be consumed by external devices, via one or more of the interchangeable modules 901-1 to 901-n shown in FIG. 9.

A detailed exemplary embodiment of one of the interchangeable modules 901-1 to 901-n shown in FIG. 9 is illustrated as module 1 901-1. Module 1 901-1 may comprise, for example, a connector interface 903-1 which is used for connection to, e.g., a wire or cable connector 916-1 (also shown as, e.g., connector 706 in FIG. 7). As described before, cable connector 916-1 (or connector 706) is used to interconnect different modules together, and/or also to connect with the central monitoring controller 911, thru a multiplexer or a T connector 920 of FIG. 9. The connector 916-1 is also used, e.g., to provide wiring for power distribution, Ethernet and/or other audio, visual or communications wiring distribution.

Exemplary module 1 901-1 may also comprise a processor 902-1 for processing, controlling and monitoring of the different components and functions of the module 1 901-1, through a processor bus 906-1. In addition, for example, each module 901-1 to 901-n in FIG. 9 has one or more interchangeable functional specific components 904-1 to 904-n. Each functional component corresponds to a specific function being provided by exemplary modules 901-1 to 901-n. For example, module 1 901-1 may comprise an AC power socket and thus it would have a functional specific component of AC Power 904-1, as shown in FIG. 9. The AC Power component 904-1 would provide, for example, monitoring and measuring of AC power usage through the AC power outlet socket of module 901-1. In a non-limited alternative, an exemplary AC power outlet module 901-1 according to the present principles would not require a functional component for providing an AC power outlet, since the AC power may be supplied directly from the module connector 916-1 without any additional monitoring or conditioning.

In addition, another exemplary functional component, “USB DC Supply” 904-2, is shown as one of the functional components of the exemplary module 901-1. This functional component may be, for example, a hardware board (with appropriate firmware if necessary) which would provide the functionality of providing the USB DC power charging function. Various USB DC charging circuitries are well known in the art. Exemplary circuits are described, for example, in US 20130175977, titled “Current Selectable USB Charger”, and the teachings therein are hereby incorporated by reference in its entirety.

Similarly, a WIFI extender or router functional component 904-n is shown as being incorporated in the interchangeable module n 901-n in FIG. 9 for providing WIFI wireless communication functionality. The functional component 904-n would be, e.g., a WIFI wireless router card with the appropriate software or firmware incorporated for providing, e.g., IEEE802.11N and/or IEEE802.11AC compliant wireless services. Such circuitries are also well known in the art and may be provided via chipsets such as e.g., Broadcom BCM4329 and BC4358 from Broadcom Corporation. In addition, wireless communications are described, for example, in U.S. Pat. No. 8,386,898 titled “Method and Apparatus for Data Transmission Using Multiple Transmit Antennas” and U.S. Pat. No. 8,355,475 titled “Diversity Technique for Wireless Communications”, the teachings of both are hereby incorporated by reference in their entirety. Therefore, by changing the functional components 904-1 to 904-n, one or more functions may be provided by different modules 901-n to 901-n according to the present principles.

FIGS. 10 to 12 illustrate different interchangeable modules according to the present principles. For example, FIG. 10 shows a module 1000 which is capable of providing an AC power switch 1010 and an Ethernet connector 1020. FIG. 11 shows an exemplary module 1100 which is capable of providing a USB DC power charge socket 1110 and an AC power socket 1120. FIG. 12 shows a module 1200 which is capable of providing a WIFI extender or router, with a display 1210 indicating the WIFI signal strength, and an Ethernet connector 1220 on the bottom for providing Ethernet wired communication. As noted before, one skilled in the art can readily appreciate that the different functionalities may be implemented by incorporating the corresponding one or more functional components for providing the corresponding functionalities as described previously in connection with FIG. 9. In addition, one skilled in the art can also readily appreciate that other functionalities such as Bluetooth, HDMI, etc., and different combinations of different functionalities may be implemented as well known in the art, without departing from the teachings of the present principles.

FIG. 13 shows an exemplary module 1300 which does not have an integrated face place according to the present principles. As shown in FIG. 13, the module 1300 is already plugged into, mounted and seated to an exemplary work box 1310, without a face plate.

FIG. 14 shows an exemplary non-integrated face plate 1420 which may be used to additionally cover exemplary module 1300 mounted to the work box 1310 as shown in FIG. 13. In addition, an exemplary quick-mount wall cover face plate 1410 is shown covering a work box (not seen).

The exemplary quick-mount wall cover face plate 1410 shown in FIG. 4 may be used to quickly cover over a space in a wall, in which a work box may already reside. Additionally, the wall cover face plate 1410 may be quickly removed so that one of the exemplary modules according to the present principles may be easily mounted to an already existing work box if a need suddenly arises, without any tool. The quick cover face plate 1410 also provides an ecstatically-pleasing finish as shown in FIG. 4.

Element 1400 of FIG. 14 shows how an exemplary face plate cover such as that shown as 1410 or 1420 may be constructed so that the face plate 1410 or 1420 may be mounted to a work box, or as an alternative, mounted to a space in the wall even without a work box. As shown in FIG. 14, a face plate 1400 may have a plurality of protrusions 1480-1 to 1480-n, for example, such as tabs or latches which would protrude or extend outwardly, in the rear ward direction away from the front face and in the direction of a wall. The front face 1450 (shown as having slanted lines) of the face plate 1400 is shown as transparent for the purpose of being able to illustrate the features of the face plate 1450 which would otherwise be obstructed by the front face 1450. Preferably, exemplary protrusions 1480-1 to 1480-n would have an approximately length of about 0.5 to 1 inch. In addition, the long side of the face plate 1400 may have 3 protrusions and the shorter side of the face plate 1400 may have 2 protrusions. Therefore, the exemplary face plate 1400 may be simply pushed into e.g., a work box 1310 shown in FIG. 13 and face plate 1400 will be mounted to the work box 1300 via the plurality of protrusions, tabs or latches 1480-1 to 1480-n as shown in 1410 or 1420 of FIG. 14.

The foregoing has been provided by way of exemplary embodiments and non-limiting examples a description of the method and systems contemplated by the inventor. It is clear that various modifications and adaptations may become apparent to those skilled in the art in view of the description. However, such various modifications and adaptations fall within the scope of the teachings of the various embodiments described above.

The embodiments described herein may be implemented in, for example, a method or a process, an apparatus, a software program, a data stream, or a signal. Even if only discussed in the context of a single form of implementation (for example, discussed only as a method), the implementation of features discussed above may also be implemented in other forms (for example, an apparatus or program). An apparatus may be implemented in, for example, appropriate hardware, software, and firmware. The methods may be implemented in, for example, an apparatus such as, for example, a processor, which refers to processing devices in general, including, for example, a computer, a microprocessor, an integrated circuit, or a programmable logic device. Processors also include communication devices, such as, for example, computers, cell phones, portable/personal digital assistants (“PDAs”), and other devices that facilitate communication of information between end-users.

Reference to “one embodiment” or “an embodiment” or “an exemplary embodiment” or “one implementation” or “an implementation” of the present principles, as well as other variations thereof, mean that a particular feature, structure, characteristic, and so forth described in connection with the embodiment is included in at least one embodiment of the present principles. Thus, the appearances of the phrase “in one embodiment” or “an exemplary embodiment” or “in an embodiment” or “in one implementation” or “in an implementation”, as well any other variations, appearing in various places throughout the specification are not necessarily all referring to the same embodiment.

As will be evident to one of skill in the art, implementations may produce a variety of signals formatted to carry information that may be, for example, stored or transmitted. The information may include, for example, instructions for performing a method, or data produced by one of the described embodiments. For example, a signal may be formatted to carry the bitstream of a described embodiment. Such a signal may be formatted, for example, as an electromagnetic wave (for example, using a radio frequency portion of spectrum) or as a baseband signal. The formatting may include, for example, encoding a data stream and modulating a carrier with the encoded data stream. The information that the signal carries may be, for example, analog or digital information. The signal may be transmitted over a variety of different wired and/or wireless links, as is known. The signal may be stored on a processor-readable medium.

While several embodiments have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present embodiments. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings herein is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereof, the embodiments disclosed may be practiced otherwise than as specifically described and claimed. The present embodiments are directed to each individual feature, system, article, material and/or method described herein. In addition, any combination of two or more such features, systems, articles, materials and/or methods, if such features, systems, articles, materials and/or methods are not mutually inconsistent, is included within the scope of the present embodiment.

1. A system comprising:
a plurality of interchangeable modules;
a central controller configured to monitor and control the plurality of interchangeable modules;
wherein at least one of the plurality of interchangeable modules comprises:
a power supply socket for supplying power to an external device;
an integrated locking mechanism;
a protrusion coupled to the integrated locking mechanism;
a module connector;
an integrated face plate positioned in front side of the at least one of the plurality of interchangeable modules; and
wherein the protrusion is extended by the integrated locking mechanism in one position of the integrated locking mechanism to secure the at is least one of the plurality of interchangeable modules to a work box, and the integrated face plate is flush mounted against a wall when the at least one of the plurality of interchangeable modules is mounted to the work box via the module connector.

2. The system of claim 1 wherein the at least one of the plurality of interchangeable modules is mounted to the work box via the module connector with a mating connector of the work box.

3. The system of claim 2 wherein power is supplied to the power supply socket via the module connector.

4. The system of claim 1 wherein the power supply socket is one of: 1) AC power supply, and) DC USB power supply.

5. The system of claim 1 where in the protrusion is a latch.

6. The system of claim 1 wherein the protrusion is positioned on one of: 1) vertical side, and 2) horizontal side of the at least one of the plurality of interchangeable modules.

7. The system of claim 1 where in the integrated locking mechanism is pushable.

8. The system of claim 4 wherein the AC power supply is supplied to the power supply socket via a separate module connector.

9. An interchangeable module comprises:
a power supply socket for supplying power to an external device;
an integrated locking mechanism;
a protrusion coupled to the integrated locking mechanism;
a module connector;
an integrated face plate positioned in front side of the interchangeable module; and
wherein the protrusion is extended by the integrated locking mechanism in one position of the integrated locking mechanism to secure the interchangeable module to a work box, and the integrated face plate is flush mounted against a wall when the interchangeable module is mounted to the work box via the module connector.

10. The interchangeable module of claim 9 wherein the interchangeable module is mounted to the work box via the module connector with a mating connector of the work box.

11. The interchangeable module of claim 10 wherein power is supplied to the power supply socket via the module connector.

12. The interchangeable module of claim 9 wherein the power supply socket is one of: 1) AC power supply, and) DC power supply.

13. The interchangeable module of claim 9 where in the protrusion is a latch.

14. The interchangeable module of claim 9 wherein the protrusion is positioned on one of: 1) vertical side, and 2) horizontal side of the at least one of the plurality of interchangeable modules.

15. The interchangeable module of claim 9 where in the integrated locking mechanism is push-able.

16. The interchangeable module of claim 12 wherein the AC power supply is supplied to the power supply socket via a separate module connector.

17. The interchangeable module of claim 15 wherein in one position of the push-able locking mechanism the protrusion is extended.

18. A module comprises:
at least one of a plurality of functional components;
an integrated locking mechanism;
a protrusion coupled to the integrated locking mechanism;
a module connector;
an integrated face plate positioned in front side of the module; and
wherein the protrusion is extended by the integrated locking mechanism in one position of the integrated locking mechanism to secure the module to a work box and the integrated face plate is flush mounted against a wall when the module is mounted to the work box via the module connector.

19. The module of claim 18 wherein the at least of one of a plurality of functional components is for wireless communication.

20. The module of claim 18 wherein the at least of one of a plurality of functional components is for USB charging.

21. A face plate for a work box, comprising:
a front face;
a plurality of protrusions on one or more sides of the face plate and extending outwardly in the rear ward direction away from the front face; and
wherein the face plate is configured to be mounted to the work box by the plurality of protrusions.
